(19) United States
(12) Patent Application Publication
(10) Pub. No.: US 2013/0022837 A1
(43) Pub. Date: Jan. 24, 2013

(54) FILM AND METHOD FOR MAKING FILM

(71) Applicant: CHUNG-PEI WANG, Tu-Cheng (TW)

(72) Inventor: CHUNG-PEI WANG, Tu-Cheng (TW)

(73) Assignee: HON HAI PRECISION INDUSTRY CO., LTD., Tu-Cheng (TW)

(21) Appl. No.: 13/245,875

(22) Filed: Sep. 27, 2011

(30) Foreign Application Priority Data
Jul. 20, 2011 (TW) 100125543

(51) Int. Cl. B32B 15/01; C23C 14/14; C23C 14/34; B05D 3/00

(52) U.S. Cl. 428/661; 427/295; 204/192.15

(57) ABSTRACT

A film is coated on a substrate made of stainless steel, and includes a first buffer layer, a second buffer layer, and a third buffer layer which are positioned on the substrate from a near end to a far end. The first buffer layer is made of Cr. The second buffer layer is made of Ti and Cr. The color layer is made of Ti and Cr.

### BACKGROUND

1. Technical Field

The present disclosure relates to films and, particularly, to a film having maximum wear-resistant performance.

2. Description of Related Art

Shells of electronic devices need to be coated with films for protecting the shells. Because the films rub against other objects that are carried in a pocket at the same time as the electronic device, for example. Improving the wear-resistant performance of the shell becomes more and more important.

Therefore, it is desirable to provide a film and method for making the film that can overcome the above-mentioned limitations.

### BRIEF DESCRIPTION OF THE DRAWINGS

Many aspects of the embodiments should be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic view of a film, according to an exemplary embodiment.

FIG. 2 is a flow chart of a method for making the film of FIG. 1.

### DETAILED DESCRIPTION

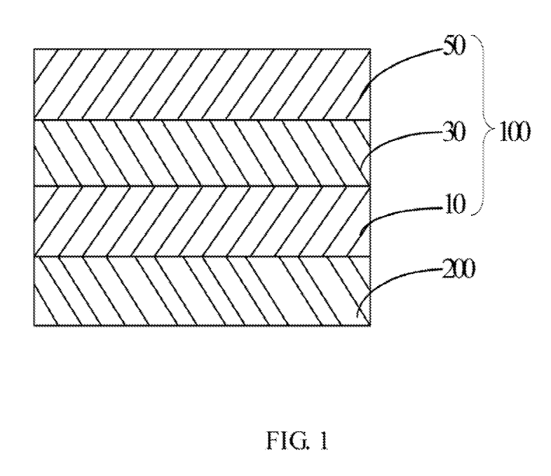

Referring to FIG. 1, a film 100, according to an exemplary embodiment, is coated on a substrate 200. The film 100 includes a first buffer layer 10, a second buffer layer 30, and a color layer 50, which are arranged on the substrate 200 in this order from a near end to a far end. The substrate 200 may be a shell of an electronic device.

The substrate 200 is made of stainless steel in this embodiment.

The first buffer layer 10 is made of chromium (Cr). The thickness of the first buffer layer 10 is about 0.2 to about 0.25 micrometers (μm).

The second buffer layer 30 is made of titanium (Ti) and chromium (Cr). The mass ratio of Ti to Cr is about 1:1. The thickness of the second buffer layer 30 is about 0.3 to about 0.35 μm.

The color layer 50 is made of Ti and Cr. The mass ratio of Ti to Cr is about 3:1. The thickness of the second buffer layer 50 is about 0.4 to about 0.5 μm.

Because the first buffer layer 10 and the second buffer layer 30 are arranged between the substrate 200 and the color layer 50, the wear-resistant performance of the film 100 is strengthened.

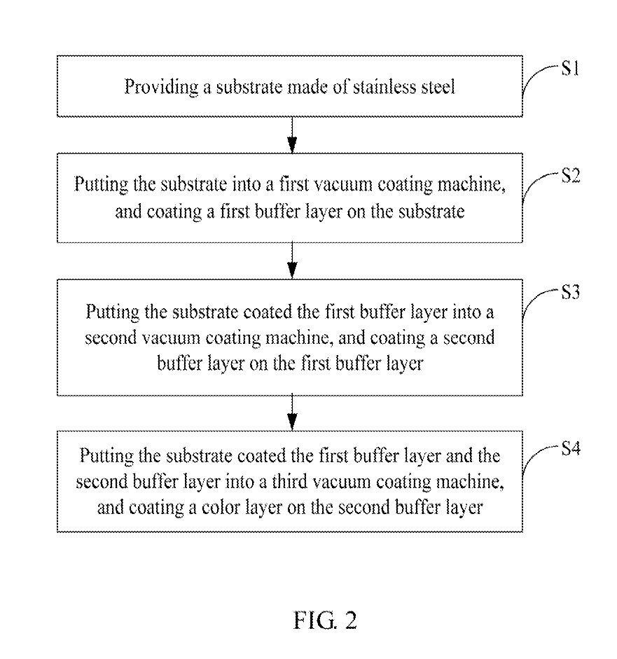

Referring to FIG. 2, an embodiment of a method for making the film 100 includes the following steps:

S 1: a substrate 200 made of stainless steel is provided. The substrate 200 may be a shell of an electronic device.

S 2: the substrate 200 is put into a first vacuum coating machine, and is coated with a first buffer layer 10 on the substrate 200 by a magnetron sputtering method. In one embodiment, the vacuum pressure of the first vacuum coating machine is about 0.5 to about 0.8 Pascals (Pa). The target is Cr. The power of an electron impact ion source is about 10 to about 12 KW. The voltage of the bias generator is about 200 to about 220 V. The coating time period is about 600 seconds (s). The thickness of the first buffer layer is about 0.2 to about 0.25 μm. The gas filled in the first vacuum coating machine is argon (Ar). The flow rate of Ar is about 500 standard cube centimeters per minute (sccm).

S3: the substrate 200 coated with the first buffer layer 10 is put into a second vacuum coating machine, and is further coated with a second buffer layer 30 on the first buffer layer 10 by a magnetron sputtering method. In one embodiment, the vacuum pressure of the second vacuum coating machine is about 0.5 to about 0.8 Pa. The two targets are Ti and Cr. Both of the powers of two electron impact ion sources respectively used for bombarding the two targets are about 10 to about 12 KW. Both of the voltages of the two bias generators are about 200 to about 220 V. The coating time period is about 600 seconds. The thickness of the second buffer layer is about 0.3 to about 0.35 μm. The gas filled in the second vacuum coating machine is Ar. The flow rate of Ar is about 500 sccm.

S4: the substrate 200 coated with the first buffer layer 10 and the second buffer layer 30 is put into a third vacuum coating machine, and is coated with a color layer 50 on the second buffer layer 30 by a magnetron sputtering method. In one embodiment, the vacuum pressure of the third vacuum coating machine is about 0.5 to about 0.8 Pa. The two targets are Ti and Cr. The power of the electron impact ion source used for bombarding the Ti is about 30 to about 36 KW. The power of the electron impact ion source used for bombarding the Cr is about 10 to about 12 KW. Both of the voltages of the two bias generators are about 80 to about 85 V. The coating time period is about 2700 seconds. The thickness of the color layer is about 0.4 to about 0.5 μm. The gas filled in the third vacuum coating machine is Ar and oxygen (O₂). The ratio of the flow rate of the Ar to the O₂ is about 1:3. The flow rate of Ar is about 200 sccm. The flow rate of O₂ is about 600 sccm.

In other embodiments, the first buffer layer, the second buffer layer, and the color layer may be coated using other coating methods such as a vacuum evaporation technique, for example.

In other embodiments, the first vacuum coating machine, the second vacuum coating machine, and the third vacuum coating machine may be one vacuum coating machine. After the substrate has been coated with one film, the vacuum coating machine needs to be vacuumized, and then the other film is coated on the substrate.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A film for being coated on a substrate, comprising:
a first buffer layer comprised of Cr;
a second buffer layer comprised of Ti and Cr and positioned on the first buffer layer; and
a color layer comprised of Ti and Cr and positioned on the second buffer layer.

2. The film of claim 1, wherein the mass ratio of Ti to Cr of the second buffer layer is about 1:1.

3. The film of claim 1, wherein the mass ratio of Ti to Cr of the color layer is about 3:1.

4. The film of claim 1, wherein a thickness of the first buffer layer is about 0.2 to about 0.25 μm.

5. The film of claim 1, wherein a thickness of the second buffer layer is about 0.3 to about 0.35 μm.

6. The film of claim 1, wherein a thickness of the color layer is about 0.4 to about 0.5 μm.

7. A method of making a film, comprising:
providing a substrate made of stainless steel;
putting the substrate into a first vacuum coating machine to coat a first buffer layer made of Cr on the substrate;
putting the substrate coated with the first buffer layer into a second vacuum coating machine to coat a second buffer layer made of Ti and Cr on the first buffer layer;
putting the substrate coated with the first and second buffer layers into a third vacuum coating machine to coat a color layer made of Ti and Cr on the second buffer layer.

8. The method of claim 7, wherein the mass ratio of Ti to Cr of the second buffer layer is about 1:1.

9. The method of claim 7, wherein the mass ratio of Ti to Cr of the color layer is about 3:1.

10. The method of claim 7, wherein a thickness of the first buffer layer is about 0.2 to about 0.25 μm.

11. The method of claim 7, wherein a thickness of the second buffer layer is about 0.3 to about 0.35 μm.

12. The method of claim 7, wherein a thickness of the color layer is about 0.4 to about 0.5 μm.

13. The method of claim 7, wherein a vacuum pressure of the first vacuum coating machine is about 0.5 to about 0.8 Pa, the first vacuum coating machine comprises a target of Cr, the power of an electron impact ion source is about 10 to about 12 KW, the voltage of a bias generator of the first vacuum coating machine is about 200 to about 220V, the coating time period is about 600 seconds, a thickness of the first buffer layer is about 0.2 to about 0.25 μm, a gas filled in the first vacuum coating machine is Ar, the flow rate of Ar is about 500 sccm.

14. The method of claim 7, wherein a vacuum pressure of the second vacuum coating machine is about 0.5 to about 0.8 Pa, the second vacuum coating machine comprises a target of Ti and a target of Cr, both of the powers of two electron impact ion sources respectively configured for bombarding the two targets are about 10 to about 12 KW, both of the voltages of two bias generators of the second vacuum coating machine are about 200 to about 220 V, the coating time period is about 600 seconds, a thickness of the second buffer layer is about 0.3 to about 0.35 μm, a gas filled in the second vacuum coating machine is Ar, the flow rate of Ar is about 500 sccm.

15. The method of claim 7, wherein a vacuum pressure of the third vacuum coating machine is about 0.5 to about 0.8 Pa, the third vacuum coating machine comprises a target Ti and a target of Cr, the power of an electron impact ion source configured for bombarding the target of Ti are about 30 to about 36 KW, the power of another electron impact ion source configured for bombarding the target of Cr are about 10 to about 12 KW, both of the voltages of two bias generators of the third vacuum coating machine are about 80 to about 85 V, the coating time period is about 2700 seconds, a thickness of the color layer is about 0.4 to about 0.5 μm, a gas filled in the third vacuum coating machine is Ar and O₂, the ratio of the flow rate of Ar and O₂ is about 1:3.

16. The method of claim 15, wherein the flow rate of Ar is about 200 sccm, the flow rate of O₂ is about 600 sccm.
